(19) United States
(12) Patent Application Publication
(10) Pub. No.: US 2026/0024581 A1
(43) Pub. Date: Jan. 22, 2026

(54) ANALOG COMPUTING UNIT FOR REPRESENTING NEGATIVE WEIGHTS

(71) Applicant: Intelligent HW, Inc., Lewes, DE (US)

(72) Inventor: Hwan Jun ZANG, Seongnam-si (KR)

(21) Appl. No.: 19/271,092

(22) Filed: Jul. 16, 2025

(30) Foreign Application Priority Data
Jul. 18, 2024 (KR) 10-2024-0095195
Jun. 25, 2025 (KR) 10-2025-0084008

(51) Int. Cl. G11C 11/54; G11C 7/16; G11C 16/04; G11C 16/26

(52) U.S. Cl. CPC G11C 11/54; G11C 7/16; G11C 16/0416; G11C 16/26; G11C 2216/04

(57) ABSTRACT

An object is to provide a new analog computing unit capable of reducing the size of an analog computing unit and reducing the amount of power consumption by reducing use of analog-to-digital converters (ADCs) to ¼ as compared to prior arts. In an analog computing unit according to one embodiment, a flash memory cell array included in the unit has the structure in which unlike the prior arts, WLs and CGs are connected in a row direction, and EGs and RLs/BLs are connected in a column direction. Accordingly, the array has the structure in which even-numbered cells for negative weights in a column and odd-numbered cells for positive weights in the column form pairs in a read NN mode, or odd-numbered cells for negative weights in a column and even-numbered cells for positive weights in the column form pairs in a read mode.

### CROSS REFERENCE TO RELATED APPLICATION

The present application claims priority to Korean Patent Application No. 10-2024-0095195, filed on Jul. 18, 2024 and Korean Patent Application No. 10-2025-0084008, filed on Jun. 25, 2025 the entire contents of which are incorporated here for all purposes by this reference.

### BACKGROUND OF THE INVENTION

### 1. Field of the Invention

The present invention relates to an analog computing unit for analog computing in a computing accelerator for implementing an artificial intelligence network, and in particular, to an analog computing unit including a flash memory cell array for deriving a computing result of positive weights and negative weights using the same analog-to-digital converters (ADCs).

### 2. Description of the Related Art

A human brain includes a number of neural cells called as neurons. Each neuron is connected to hundreds or thousands of other neurons via connection parts called as synapses. In order to imitate human intelligence, a model that models the operation principle of biological neurons and the connection relationship between the neurons is called as an artificial neural network (ANN) model.

An artificial neural network may imitate a biological neural network (the central nervous system, specially the brain of an animal), depend on multiple inputs, and be used to estimate or approximate a generally unknown function. In general, an artificial neural network includes layers of interconnected “neurons” that exchange messages to each other.

A deep neural network (DNN) is a type of an artificial neural network, and exhibits excellent performance in various fields including image recognition, speech recognition, natural language processing, a recommendation system, or the like. In particular, the performance of the DNN is continuously improved based on massive data and higher computation power, so that the DNN has become a core technology in the artificial intelligence field.

Such a DNN has multiple hidden layers between an input layer and an output layer. Each of the layers is constituted of a number of neurons (nodes), and neurons of adjacent layers are connected to each other. In such a DNN, input data is sequentially propagated from the input layer to the output layer. Each neuron receives an input from the neurons of the previous layer, computes weights, and transfers an output value obtained through an activation function to the next layer.

In order to implement such a DNN, a digital computing apparatus using digital computing has been developed. However, the digital computing apparatus exhibits high accuracy, but massive energy consumption is inevitable due to limited parallel processing, a memory barrier caused by a Von Neumann computing structure, or the like. In addition, application to various fields is problematic due to a large size and a resulting high price, etc.

The traditional Von Neumann computing structure has separate processors and memories. In order to process data in this structure, the data should be transferred from memories to processors and then transferred to the memories again. This process causes a memory barrier and massive energy consumption, which is more severe in artificial intelligence (AI) computation that requires massive data processing. Accordingly, a solution has been required for reducing a memory barrier and excessive energy consumption by enabling in-memory data storage and computation at the same time.

In recent technical trends, a computing apparatus based on analog computing using computing in memory (CIM) is used for addressing such issues. The analog computing enables massive parallel processing without a memory barrier, a great reduction in energy consumption, and manufacturing at a low cost, so that a lot of research and development is being conducted. In particular, an analog computing unit using a non-volatile memory (NVM) such as a flash memory is also actively being developed.

In analog computing, storage and computing are performed in the same device. To this end, a computing apparatus includes an analog computing unit for analog computing, and the analog computing unit includes a memory cell array composed of NVMs such as flash memories, and analog circuits such as analog-to-digital converters (ADCs), digital-to-analog converters (DACs), or the like. Typically, the computing apparatus has the structure in which an input signal is applied to the non-volatile memory cell array via the DACs, multiplication and accumulation computations (MACs) are performed, and then analog signals are converted into digital signals via the ADCs.

The analog computing unit for analog computing stores weights for MAC computations in NVM cells. In order to prevent infinite divergence caused by the characteristics of MAC computations that are combinations of multiplications and additions, positive weights and negative weights are necessary and accordingly memory cells for positive values and memory cells for negative values are required. Accordingly, ADCs for deriving positive weight computation results and ADCs for deriving negative weight computation results come to coexist. In many cases, a split-gate NOR flash cell array is used in an analog computing unit in order to store weights. Normally, the split-gate NOR flash cell array has the structure in which two memory cells are symmetrically disposed.

Korean Patent Application Laid-Open No. 10-2022-0125305, which is incorporated herein by reference, discloses an artificial neural network using at least one split-gate NOR flash cell array as a synapse. The non-volatile memory cell array operates as an analog neuromorphic memory. A term “neuromorphic” used in the application means a circuit for implementing a nervous system model. The analog neuromorphic memory includes a first plurality of synapses configured to receive a first plurality of inputs and generate a first plurality of outputs therefrom, and a first plurality of neurons configured to receive the first plurality of outputs. The first plurality of synapses include a plurality of memory cells, wherein each of the memory cells is formed within a semiconductor substrate, and includes a separate source region and drain region between which a channel region extends, a floating gate FG disposed on a first portion of the channel region and insulated therefrom, and a non-floating gate disposed on a second portion of the channel region and insulated therefrom. Each of the plurality of memory cells is configured to store a weight corresponding to the number of electrons on the floating gate. The plurality of memory cells are configured to multiply the first plurality of inputs by the stored weights to generate the first plurality of outputs.

FIG. 1 illustrates 4-split gate NOR memory cell 410 including a source region (SL) 14, a drain region (BL) 16, a floating gate 20 on a first portion of a channel region 18, a selection gate (SG) 22 on a second portion of the channel region 18 (combined to word lines (WL)), a control gate (CG) 28 on the floating gate (FG) 20, and an erase gate (EG) 30 on the source region 14. Such a configuration is disclosed in Korean Patent Application Laid-Open No. 10-2022-0125305 that is incorporated herein by reference for all purposes. Here, all the gates are non-floating gates except for the floating gate 20, which means that the gates are electrically connected or connectable to a voltage source. A program is performed by injecting heated electrons from the channel region 18 onto the floating gate 20. Erasure is performed by tunneling the electrons from the floating gate 20 to the erase gate 30.

Table 1 shows a typical range of a voltage that may be applied to a terminal of the memory cell in order to perform read, erase, and program operations.

TABLE 1
Operation of flash memory cell of FIG. 1

| | WL/SG | | BL | | CG | | EG | | SL | |
|---|---|---|---|---|---|---|---|---|---|---|
| read E | 1.4 | V | 0.6 | V | 1.8 | V | 0 | V | 0 | V |

| read V | 1.4 | V | 0.6 | V | 0 V-VDD | | 0 V-VDD | 0 | V |
|---|---|---|---|---|---|---|---|---|---|
| read NN | 1.4 | V | 0.6 | V | 0 V-VDD | | 0 V~VDD | 0 | V |
| erase | 0 | V | 0 | V | 0 | V | 8 V-12 V | 0 | V |

| | | | | | | | | | |
|---|---|---|---|---|---|---|---|---|---|
| program D | 0.8 | V | to 0.5 uA | 10.5 | V | 4.5 | V | 4.5 | V |

| | | | | | | |
|---|---|---|---|---|---|---|
| program A | 0.8 | V | to 0.5 uA | 3 V-10 V | 3 V-5 V | 3 V-5 V |

Here, “read E” denotes a cell read mode during 1-bit program and erase operations. “read V” denotes a cell read mode during a 5-bit program operation. “read NN” denotes a cell read mode performed for an AI operation by an ADC. “program D” denotes an 1-bit program operation mode. “program A” denotes a 5-bit program operation mode for an AI operation.

### SUMMARY OF THE INVENTION

An object of the invention is to provide a new analog computing unit capable of saving a layout area for ADCs, reducing the size of the analog computing unit, and reducing the amount of power consumption during operation by integrating ADCs for positive weights and ADCs for negative weights caused by the characteristics of MAC computations and using only half of ADCs as compared to prior arts in an analog computing unit for implementing an artificial neural network.

To achieve such objects as described above, an analog computing unit for an artificial neural network includes an array of non-volatile memory cells, the cells being arranged with rows and columns, wherein the columns are arranged such that first columns composed of minus cells for storing negative weights and second columns composed of plus cells for storing positive weights are alternately arranged, row lines and bit lines extending in a row direction are alternately arranged in a column direction, and in the cells arranged in the row direction, sources and drains are alternately arranged along the row lines or the bit lines, the cells arranged in the same column are connected along the word line, in a cell read mode, the cells arranged along the rows are turned on or off alternately one by one and the cells arranged along the columns are turned on or off alternately two by two, and currents flowing from the plus cells and the minus cells arranged along the rows are canceled as much as corresponding values, and then only resulting currents are transferred to the bit lines.

In addition, the analog computing unit according to an embodiment of the present invention may further include analog-to-digital converters (ADCs) for sensing outputs from the respective bit lines to convert the outputs to digital signals.

In addition, in the analog computing unit according to an embodiment of the present invention, the ADCs may be disposed in the respective bit lines.

In addition, in the analog computing unit according to an embodiment of the present invention, the cells arranged in the respective columns may be connected through a first word line and a second word line, the first word line and the second word line may connect the cells arranged in the columns alternately two by two, and control gates (CG) of the cells arranged at each of the columns may be connected through one line.

In addition, in the analog computing unit according to an embodiment of the present invention, an erase gate line extending in the row direction may connect erase gates (EG) of each of the columns alternately one by one.

In addition, in the analog computing unit according to an embodiment of the present invention, the cell array may include a column set of non-volatile memory cells used as a duplication cell array.

In addition, in the analog computing unit according to an embodiment of the present invention, the cell may be a split-gate flash memory cell.

### BRIEF DESCRIPTION OF THE DRAWINGS

FIG. 1 illustrates the structure and disposition of a flash memory cell according to a prior art;

FIG. 2 illustrates a flash memory cell array and an ADC connected thereto according to a prior art;

FIG. 3 illustrates example positive weights and negative weights;

FIG. 4 illustrates a read NN mode of a flash memory cell array according to an embodiment of the present invention; and

FIG. 5 illustrates a read NN mode of a flash memory cell array according to an embodiment of the present invention.

### DETAILED DESCRIPTION OF THE EXEMPLARY EMBODIMENTS

Hereinafter, with reference to the attached drawings, embodiments of the present application will be described in detail so that a person skilled in the art may easily carry out the embodiments of the present application. However, the present application may be embodied in various forms different from each other and thus is not limited to the embodiments described herein.

In addition, in order to clearly describe the present application in the drawings, portions unrelated to the description have been omitted, and similar reference numerals for drawings have been attached to similar portions throughout the specification.

In addition, if certain parts are described as being “connected” to other parts, they are not only “directly connected” to the other parts, but also “electrically connected” to the other parts with any other device intervened therebetween.

Throughout the specification, when a member is located “on”, “over”, “on top of”, “under”, “below”, “on bottom of” another member, it includes not only when the member is in contact with the other member, but also when there is another member between the two members.

Throughout the specification of the present application, in a case where a certain part is said to “include” a certain component, it means that other components may be further included rather than excluding other components, unless the context specifically states otherwise.

Terms such as “about” and “substantially” which are used in the present specification are used to mean to be at the numerical value or close to the numerical value in a case where allowable errors for intrinsic manufacturing and intrinsic substances are provided for the mentioned meaning, and they are used to prevent an unscrupulous infringer from unfairly utilizing the disclosed content in which accurate or absolute numerical values are mentioned to aid the understanding of the present application. In addition, throughout the specification of the application, the term “step of ˜ing” or “step of ˜” does not mean “step for ˜.”

Throughout the specification of the application, the term “a combination thereof” included in the Markush form means a mixture or combination of one or more selected from the group consisting of components, which is described in the Markush form expression, and it is used to mean that one or more selected from the group consisting of the components are included.

Throughout the specification of the application, the description “A and/or B” means “A or B”, or “A and B”.

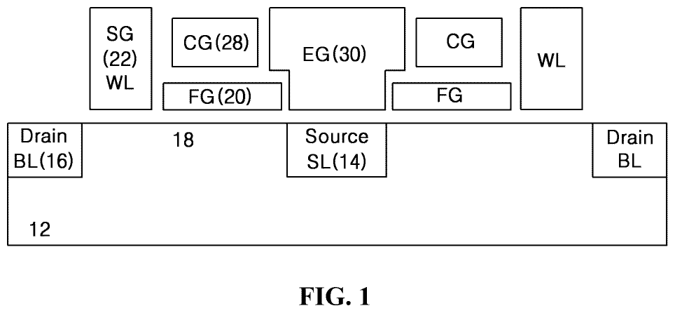

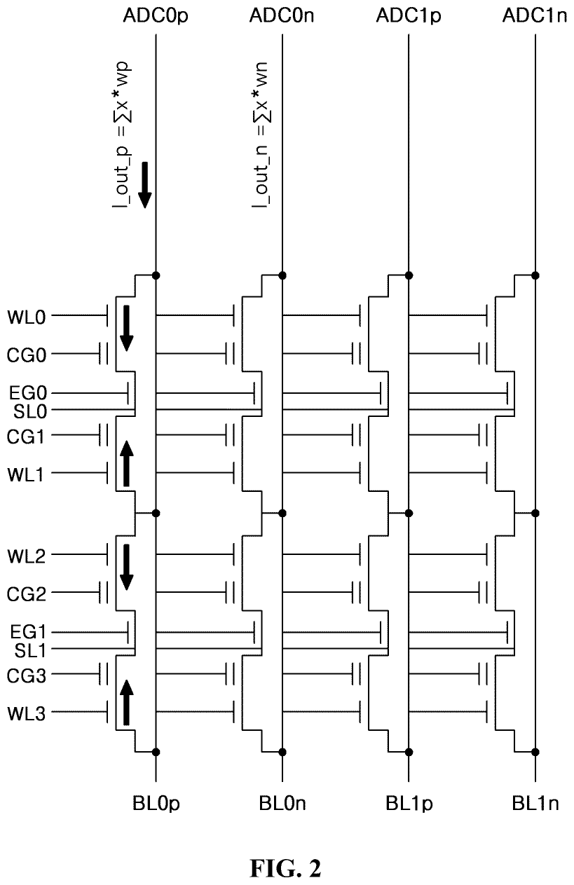

In case where a split-gate NOR flash memory is used as a nonvolatile memory in an analog computing unit, a flash memory cell array in a prior art is shown in FIGS. 1 and 2. As seen in FIG. 2, the flash memory cell array has the structure in which every two memory cells are symmetrically disposed. Through this, two memory cells share a source line (e.g., SL0), and two other memory cells share a bit line (e.g., BL0p), and accordingly memory cells arranged in one column come to share one bit line (e.g., BL0p, BL0n, or the like). ADCs are disposed at terminals of the bit lines and sense currents flowing from the memory cells through the bit lines to convert the currents into digital signals. Cells and transistors existing at other bit lines come to share a gate (e.g., WL0, CG0, EG0, SL0, CG1, WL1, or the like).

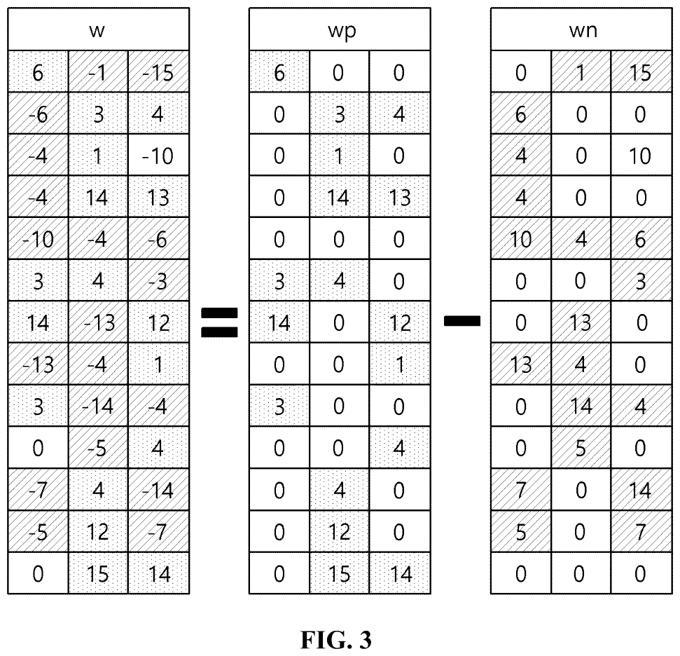

Meanwhile, in the analog computing unit for analog computing, weights are stored in non-volatile memory cells, and, as described above, the weights has positive values and negative values in order to prevent infinite divergence according to the characteristics of MAC computations (see FIG. 3). In order to represent these positive and negative weights, different bit lines are used in a prior art. For example, the positive weights are stored in memory cells connected to an even-numbered bit line BL0p, and negative weights are stored in memory cells connected to an odd-numbered bit line BL0n (see FIG. 2). When final currents are converted into digital signals through the ADCs, digital signals caused by currents flowing along positive weight bit lines are converted into positive values, and digital signals caused by currents flowing along negative weight bit lines are converted into negative values.

In this way, the positive weights and the negative weights may not be stored together in memory cells arranged in the same bit line. As positive weights are stored in memory cells connected to positive weight bit lines and negative weights are stored in memory cells connected to negative weigh bit lines, a lot of ADCs come to be used.

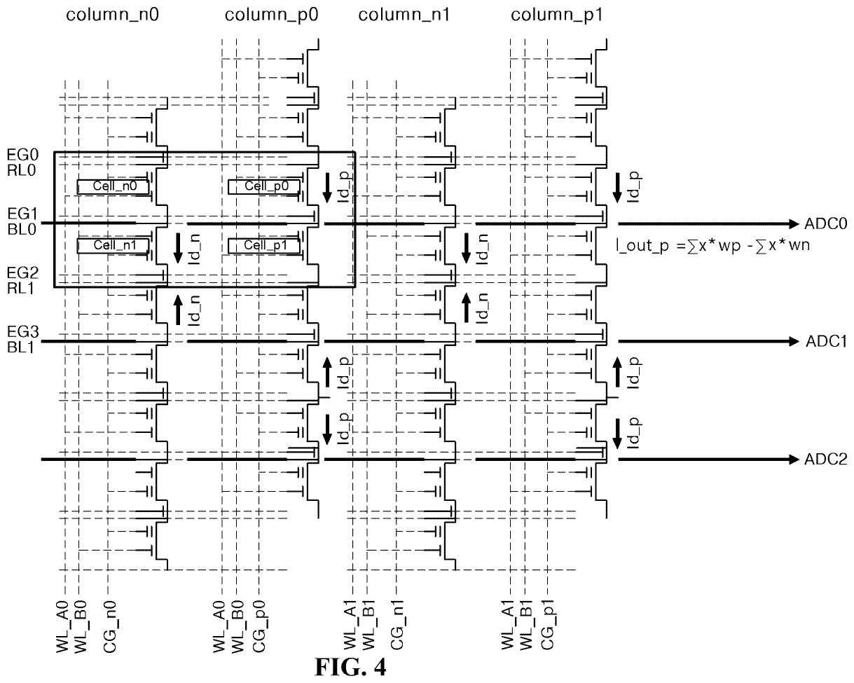

In order to overcome this, an embodiment of the present invention will be described with reference to FIG. 4. Like the existing technology, the disposition of cells themselves is performed so that columns Column_p0, Column_p1, . . . for positive weights and columns Column_n0, Column_n1, . . . for negative weights are alternately arranged. However, unlike the existing case, WLs (e.g., WL_A0, WL_B0, WL_A1, WL_B1, . . . ) and CGs (e.g., CG_n0, CG_p0, CG_n1, CG_p1, . . . ) are connected along a column direction, RLs (e.g., RL0, RL1, . . . ) and BLs (e.g., BL0, BL1, . . . ) are connected in a row direction, and ADCs (e.g., ADC0, ADC1, ADC2, . . . ) are connected to terminals of BLs. In addition, RLs and BLs have the structure in which drains or sources of columns Column_n0, Column_n1, . . . for the negative weights are alternately connected to sources or drains of columns Column_p0, Column_p1, . . . for the positive weights.

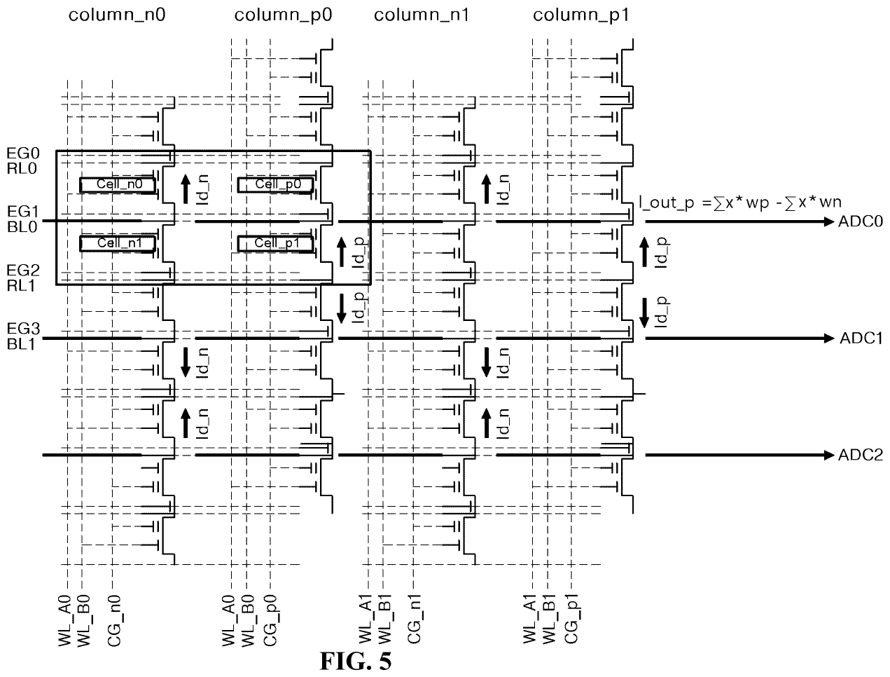

Here, when cell read mode (e.g., read NN mode) of the ADCs for an AI operation in which all of the positive weights and the negative weights should be read, Cell_n1 of Column_n0 and Cell_p0 of Column_p0 form one pair during the read mode (see FIG. 4), and Cell_n0 of Column_n0 and Cell_p1 of Column_p0 form one pair during the read mode (see FIG. 5).

Referring to FIGS. 4 and 5, Table 2 shows a typical range of a voltage that may be applied to a terminal of the memory cell in order to perform read, erase, and program operations in the invention.

TABLE 2
Operation of flash memory cell of FIG. 4

| | WL A | | WLB | | CG n | | CG p | | EG | | BL | | RL | |
|---|---|---|---|---|---|---|---|---|---|---|---|---|---|---|
| read E | 1.8 | V | 1.8 | V | 1.2 | V | 1.8 | V | 0.6 | V | 0.6 | V | 0/1.2 | V |
| read V | 1.8 | V | 1.8 | V | 0-1.2 | V | 0.6-1.8 | V | 0.6 | V | 0.6 | V | 1/1.2 | V |
| read NN(FIG. | 0 | V | 1.8 | V | 0-1.2 | V | 0.6-1.8 | V | 0.6 | V | 0.6 | V | 0/1.2 | V |
| 4) | | | | | | | | | | | | | | |
| read NN(FIG. | 1.8 | V | 0 | V | 0-1.2 | V | 0.6-1.8 | V | 0.6 | V | 0.6 | V | 0/1.2 | V |
| 5) | | | | | | | | | | | | | | |
| erase | 0 | V | 0 | V | 1.8 | V | 1.8 | V | 11.5 | V | 0 | V | 0 | V |
| program D(N | 0.8 | V | 0.8 | V | 10.5 | V | 10.5 | V | 4.5 | V | 0.5 | uA | 4.5 | V |
| cell) | | | | | | | | | | | | | | |
| program A(N | 0.8 | V | 0.8 | V | 3-10 | V | 3-10 | V | 3-5 | V | 0.5 | uA | 3-5 | V |
| cell) | | | | | | | | | | | | | | |
| program D(P | 0.8 | V | 0.8 | V | 10.5 | V | 10.5 | V | 4.5 | V | 4.5 | V | 0.5 | uA |
| cell) | | | | | | | | | | | | | | |
| program A(P | 0.8 | V | 0.8 | V | 3-10 | V | 3-10 | V | 3-5 | V | 3~5 | V | 0.5 | uA |
| cell) | | | | | | | | | | | | | | |

Here, “read E” denotes a cell read mode during 1-bit program and erase operations. “read V” denotes a cell read mode during a 5-bit program operation. “read NN” denotes a cell read mode by the ADC for an AI operation and is divided into cases of read NN (FIG. 4) and read NN (FIG. 5). “program D” denotes a 1-bit program operation mode. “program A” denotes a 5-bit program operation mode for an AI operation and is divided into a cell (N cell) for a negative weight and a cell (P cell) for a positive weight. As seen in FIGS. 4 and 5, in the invention, a current Id_p flowing through a memory cell for storing a positive weight and a current Id_n flowing through a memory cell for storing a negative weight are canceled each other as much as corresponding values and a resulting current flows through BL. Accordingly, it is not necessary to separately designate a bit line for the positive weight and a bit line for the negative weight, and one ADC is disposed at every two rows. Thereby, use of ADCs becomes reduced to ¼ as compared to a prior art.

The ADCs have a larger area than other circuits and massive energy consumption during operation, and thus the use of the ADCs becoming reduced to half may reduce the entire cost and amount of power consumption of a product.

Through the analog computing unit including the flash memory cell array according to the present invention, the entire area of a device may be reduced to lower the cost, and the power consumption during operation may also be reduced.

What is claimed is:

1. An analog computing unit for an artificial neural network comprising
an array of non-volatile memory cells, the cells being arranged with rows and columns,
wherein the columns are arranged such that first columns composed of minus cells for storing negative weights and second columns composed of plus cells for storing positive weights are alternately arranged,
row lines and bit lines extending in a row direction are alternately arranged in a column direction, and in the cells arranged in the row direction, sources and drains are alternately arranged along the row lines or the bit lines,
the cells arranged in the same column are connected along the word line,
in a cell read mode, the cells arranged along the rows are turned on or off alternately one by one and the cells arranged along the columns are turned on or off alternately two by two, and
currents flowing from the plus cells and the minus cells arranged along the rows are canceled as much as corresponding values, and then only resulting currents are transferred to the bit lines.

2. The analog computing unit according to claim 1, further comprising analog-to-digital converters (ADCs) for sensing outputs from the respective bit lines to convert the outputs to digital signals.

3. The analog computing unit according to claim 2,
wherein the ADCs are disposed in the respective bit lines.

4. The analog computing unit according to claim 1,
wherein the cells arranged in the respective columns are connected through a first word line and a second word line, the first word line and the second word line connect the cells arranged in the columns alternately two by two, and control gates (CG) of the cells arranged at each of the columns are connected through one line.

5. The analog computing unit according to claim 1,
wherein an erase gate line extending in the row direction connects erase gates (EG) of each of the columns alternately one by one.

6. The analog computing unit according to claim 1,
wherein the cell array comprises a column set of non-volatile memory cells used as a duplication cell array.

7. The analog computing unit according to claim 1,
wherein the cell is a split-gate flash memory cell.
